(19) United States
(12) Patent Application Publication
(10) Pub. No.: US 2024/0322324 A1
(43) Pub. Date: Sep. 26, 2024

(54) ELECTROCHEMICAL APPARATUS AND ELECTRICAL DEVICE

(71) Applicant: Xiamen Ampack Technology Limited, Xiamen (CN)

(72) Inventor: Xia YANG, Xiamen (CN)

(73) Assignee: Xiamen Ampack Technology Limited, Xiamen (CN)

(21) Appl. No.: 18/609,213

(22) Filed: Mar. 19, 2024

(30) Foreign Application Priority Data
Mar. 20, 2023 (CN) 202310272261.8

(51) Int. Cl. H01M 50/24; H01M 50/209; H01M 50/284; H01M 50/296

(52) U.S. Cl. CPC H01M 50/24; H01M 50/209; H01M 50/284; H01M 50/296

(57) ABSTRACT

An electrochemical apparatus includes a first housing, a second housing, and a battery cell assembly. The first housing includes a first wall, a second wall, a third wall, a fourth wall and a fifth wall, the first wall, the second wall, the third wall, the fourth wall and the fifth wall form a concave portion, and the battery cell assembly is disposed in the concave portion. The second housing is separated from the fifth wall and is connected to the first wall, the second wall, the third wall and the fourth wall. The first housing is provided with a first insulation layer, and the first insulation layer coats a part of a surface of the first wall. The first wall includes a first region, the first region is exposed to the first insulation layer, and the first region is electrically connected to the second housing.

### CROSS-REFERENCE TO RELATED APPLICATION

This application claims priority from Chinese Patent Application No. 202310272261.8, filed on Mar. 20, 2023, the content of which is incorporated herein by reference in its entirety.

### TECHNICAL FIELD

This application relates to the technical field of batteries, in particular to an electrochemical apparatus and an electrical device.

### BACKGROUND

During operation of an electrochemical apparatus containing a battery cell module, an internal pathway current generates an electric field that may affect a device in an external environment. In addition, an electric field of the external environment may also have an effect on the electrochemical apparatus.

### SUMMARY

In view of the above condition, it is necessary to provide an electrochemical apparatus, which can reduce the effect of the electric field of the external environment on the electrochemical apparatus.

Embodiments of this application disclose an electrochemical apparatus, including a first housing, a second housing, and a battery cell assembly. The first housing includes a first wall, a second wall, a third wall, a fourth wall and a fifth wall, the first wall and the third wall are disposed in a first direction, the second wall and the fourth wall are disposed in a second direction, the second wall is coupled and electrically connected to both the first wall and the third wall, the fourth wall is coupled and electrically connected to both the first wall and the third wall, the fifth wall is coupled and electrically connected to the first wall, the second wall, the third wall and the fourth wall, the first wall, the second wall, the third wall, the fourth wall and the fifth wall form a concave portion, the battery cell assembly is disposed in the concave portion, and the first direction is perpendicular to the second direction. The second housing is separated from the fifth wall and is connected to the first wall, the second wall, the third wall and the fourth wall, the second housing and the fifth wall are disposed in a third direction, and the third direction is perpendicular to the first direction and the second direction. The first housing is provided with a first insulation layer, and the first insulation layer coats a part of a surface of the first wall. The first wall includes a first region, the first region is exposed to the first insulation layer, and the first region is electrically connected to the second housing.

In the above electrochemical apparatus, the first region exposed to the first insulation layer on the first wall is electrically connected to the second housing, so that the first housing and the second housing are electrically connected to form an electrostatic shield, which is beneficial to reducing the effect of an external electric field on the interior of the electrochemical apparatus.

In some embodiments of this application, the electrochemical apparatus further includes an electrode, the electrode is disposed on the first wall and electrically connected to the first housing, and a part of the electrode is exposed outside the first housing. The electrode may be used as a grounding terminal to ground a conductive shell formed by the first housing and the second housing, which is beneficial to reducing the effect of an electric field inside the electrochemical apparatus on a device in the external environment.

In some embodiments of this application, the second housing is provided with a second insulation layer, and the second insulation layer coats a part of a surface of the second housing. The second insulation layer provides protective insulation, which is beneficial to prolonging the service life of the second housing, and also is beneficial to reducing the risk of short-circuiting of the electrochemical apparatus, and reducing the effect of the external electric field on the interior of the electrochemical apparatus.

In some embodiments of this application, the second housing includes a first connection region, the first connection region is exposed to the second insulation layer, and the first connection region is connected to the first region, such that the second housing is electrically connected to the first housing.

In some embodiments of this application, the second housing includes a first face, the first face faces the first housing, the first connection region is located on the first face, and the second insulation layer coats a part of a surface of the first face. The electrochemical apparatus further includes a first conductive member, and the first conductive member is connected to the first region and the first connection region, which is beneficial to improving the stability of electrical connection between the first housing and the second housing and to improving the seismic performance of the electrochemical apparatus.

In some embodiments of this application, the electrochemical apparatus further includes a first insulator, and a part of the first insulator is located between the first face and the first wall, and connected to the first face and the first wall. The first insulator may act as a sealing guard to reduce the risk of outside debris entering the interior of the electrochemical apparatus through a gap between the first face and the first wall.

In some embodiments of this application, the first conductive member is connected to the first insulator and coats a part of a surface of the first insulator. The support function of the first insulator is beneficial to improving the stability of connection of the first conductive member to the first region and the first connection region and further improving the seismic performance of the electrochemical apparatus.

In some embodiments of this application, in the first direction, a length of a connection region of the first connection region with the first conductive member is a, a length of the first insulator is c, and a≤ c/2, which is beneficial to ensuring a contact area between the first insulator and the second housing, and reducing the risk of outside debris entering the interior of the electrochemical apparatus through the gap between the first face and the first wall.

In some embodiments of this application, in the first direction, a length of a connection region of the first region with the first conductive member is b, and c/2≤b<c, which is beneficial to ensuring a contact area between the first conductive member and the first region, reducing the risk of failure of the electrical connection between the first conductive member and the first region, and reducing the effect of the external electric field on the interior of the electrochemical apparatus.

In some embodiments of this application, in the second direction, a length of the first conductive member is d, a length of the first insulator is e, and e/2<d<e, which is beneficial to ensuring a contact area between the first conductive member and the first region as well as between the first conductive member and the first connection region, reducing the risk of failure of the electrical connection between the first conductive member and the first region as well as between the first conductive member and the first connection region, and reducing the effect of the external electric field on the interior of the electrochemical apparatus.

In some embodiments of this application, in the second direction, a length of the first region is greater than the length of the first conductive member, which is beneficial to ensuring a contact area between the first conductive member and the first region, reducing the risk of failure of the electrical connection between the first conductive member and the first region, and reducing the effect of the external electric field on the interior of the electrochemical apparatus.

In some embodiments of this application, in the second direction, a length of the first connection region is greater than the length of the first conductive member, which is beneficial to ensuring a contact area between the first conductive member and the first connection region, reducing the risk of failure of the electrical connection between the first conductive member and the first connection region, and reducing the effect of the external electric field on the interior of the electrochemical apparatus.

In some embodiments of this application, the first insulation layer further coats a part of a surface of the third wall, the third wall includes a third region, the third region is exposed to the first insulation layer, and the third region is connected to the second housing, which is beneficial to further improving the stability of the electrical connection between the first housing and the second housing, reducing the risk of failure of the electrical connection between the first housing and the second housing, and reducing the effect of the external electric field on the interior of the electrochemical apparatus.

In some embodiments of this application, a part of the first insulator is located between the first face and the third wall, and connected to the first face and the third wall, which is beneficial to reducing the risk of outside debris entering the interior of the electrochemical apparatus through a gap between the first face and the third wall.

In some embodiments of this application, the second housing further includes a third connection region, the third connection region is exposed to the second insulation layer, and the third connection region is connected to the third region, which is beneficial to further improving the stability of the electrical connection between the first housing and the second housing, reducing the risk of failure of the electrical connection between the first housing and the second housing, and reducing the effect of the external electric field on the interior of the electrochemical apparatus.

In some embodiments of this application, the electrochemical apparatus further includes a third conductive member, and the third conductive member is connected to the third region and the third connection region, which is beneficial to improving the stability of electrical connection between the first housing and the second housing and to improving the seismic performance of the electrochemical apparatus.

In some embodiments of this application, the first insulation layer further coats a part of a surface of the second wall and a part of a surface of the fourth wall, the second wall includes a second region, the second region is exposed to the first insulation layer, the fourth wall includes a fourth region, the fourth region is exposed to the first insulation layer, and both the second region and the fourth region are connected to the second housing, which is beneficial to further improving the stability of the electrical connection between the first housing and the second housing, reducing the risk of failure of the electrical connection between the first housing and the second housing, and reducing the effect of the external electric field on the interior of the electrochemical apparatus.

In some embodiments of this application, a part of the first insulator is located between the first face and the second wall, and connected to the first face and the second wall, which is beneficial to reducing the risk of outside debris entering the interior of the electrochemical apparatus through a gap between the first face and the second wall.

In some embodiments of this application, an other part of the first insulator is located between the first face and the fourth wall, and connected to the first face and the fourth wall, which is beneficial to reducing the risk of outside debris entering the interior of the electrochemical apparatus through a gap between the first face and the fourth wall.

In some embodiments of this application, the second housing includes a second connection region, a third connection region, and a fourth connection region. The second connection region is exposed to the second insulation layer, and the second connection region is connected to the second region. The third connection region is exposed to the second insulation layer, and the third connection region is connected to the third region. The fourth connection region is exposed to the second insulation layer, and the fourth connection region is connected to the fourth region.

In some embodiments of this application, the electrochemical apparatus further includes a second conductive member, and the second conductive member is connected to the second region and the second connection region, which is beneficial to further improving the stability of electrical connection between the first housing and the second housing and to improving the seismic performance of the electrochemical apparatus.

In some embodiments of this application, the electrochemical apparatus further includes a third conductive member, and the third conductive member is connected to the third region and the third connection region, which is beneficial to further improving the stability of electrical connection between the first housing and the second housing and to improving the seismic performance of the electrochemical apparatus.

In some embodiments of this application, the electrochemical apparatus further includes a fourth conductive member, and the fourth conductive member is connected to the fourth region and the fourth connection region, which is beneficial to further improving the stability of electrical connection between the first housing and the second housing and to improving the seismic performance of the electrochemical apparatus.

In some embodiments of this application, any two of the first conductive member, the second conductive member, the third conductive member and the fourth conductive member are separated from each other when viewed in the third direction, which is beneficial to reducing the effect of contact interference between different conductive members on assembly of the first housing and the second housing, and improving the sealing performance between the first housing and the second housing.

In some embodiments of this application, the electrochemical apparatus further includes a first connector, and the first connector is connected to the electrode and the first housing, which is beneficial to improving the stability of the electrical connection between the electrode and the first housing, reducing the risk of failure of grounding of the first housing, and reducing the effect of the electric field inside the electrochemical apparatus on the device in the external environment.

In some embodiments of this application, the first connector is connected to the fifth wall.

In some embodiments of this application, the electrochemical apparatus further includes a circuit board, the circuit board is disposed in the concave portion, and the circuit board is connected to the battery cell assembly.

In some embodiments of this application, when viewed in the third direction, the circuit board is located between the first wall and the battery cell assembly.

In some embodiments of this application, the electrochemical apparatus further includes a second connector and a third connector, the second connector is disposed in the concave portion, and connected to the circuit board, and the third connector is disposed in the concave portion, and connected to the circuit board.

In some embodiments of this application, a part of the second connector is located between the battery cell assembly and the second wall, and an other part of the second connector is located between the battery cell assembly and the third wall.

In some embodiments of this application, a part of the third connector is located between the battery cell assembly and the second wall, and an other part of the third connector is located between the battery cell assembly and the third wall.

In some embodiments of this application, the electrochemical apparatus further includes a first output terminal and a second output terminal. The first output terminal is disposed on the third wall, a part of the first output terminal is exposed in the first housing, and the second connector is connected to the first output terminal. The second output terminal is disposed on the third wall, a part of the second output terminal is exposed in the first housing, and the third connector is connected to the second output terminal. The second output terminal and a third output terminal are disposed on the third wall away from the circuit board, which is beneficial to reducing the risk of short-circuiting inside the electrochemical apparatus.

Embodiments of this application further provide an electrical device, including the electrochemical apparatus described in any of the foregoing embodiments.

In the above electrical device, the first region exposed to the first insulation layer on the first wall is electrically connected to the second housing in the electrochemical apparatus, so that the first housing and the second housing are electrically connected to form an electrostatic shield, which is beneficial to reducing the effect of an external electric field on the interior of the electrochemical apparatus, and reducing the effect of performance damage of the electrochemical apparatus caused by the external electric field on the electrical device.

### BRIEF DESCRIPTION OF DRAWINGS

FIG. 1 is a schematic structural diagram of an electrochemical apparatus according to an embodiment of this application.

FIG. 2 is an exploded view of an electrochemical apparatus according to an embodiment of this application.

FIG. 3 is a view of a partial structure of an electrochemical apparatus in a third direction according to an embodiment of this application.

FIG. 4 is a schematic diagram of a partial structure of an electrochemical apparatus according to an embodiment of this application.

FIG. 5 is a sectional view of an electrochemical apparatus perpendicular to a second direction according to an embodiment of this application.

FIG. 6 is a partial enlarged view of a VI region in a structure shown in FIG. 5 according to an embodiment.

FIG. 7 is a partial enlarged view of a VI region in a structure shown in FIG. 5 according to an embodiment.

FIG. 8 is a partial enlarged view of a VI region in a structure shown in FIG. 5 according to an embodiment.

FIG. 9 is a view of a partial structure of an electrochemical apparatus in a third direction according to an embodiment of this application.

FIG. 10 is a view of a partial structure of an electrochemical apparatus in a third direction according to an embodiment of this application.

FIG. 11 is a partial enlarged view of an XI region in a structure shown in FIG. 5 according to an embodiment.

FIG. 12 is a partial enlarged view of an XI region in a structure shown in FIG. 5 according to an embodiment.

FIG. 13 is a partial enlarged view of an XI region in a structure shown in FIG. 5 according to an embodiment.

FIG. 14 is a sectional view of an electrochemical apparatus perpendicular to a first direction according to an embodiment of this application.

FIG. 15 is a partial enlarged view of an XV region in a structure shown in FIG. 14 according to an embodiment.

FIG. 16 is a partial enlarged view of an XVI region in a structure shown in FIG. 14 according to an embodiment.

FIG. 17 is a schematic structural diagram of an electrical device according to an embodiment of this application.

### DETAILED DESCRIPTION

The technical solutions in the embodiments of this application are described with reference to the accompanying drawings in the embodiments of this application. Apparently, the described embodiments are merely some rather than all of the embodiments of this application.

It is hereby noted that when a component is considered to be “connected” to another component, it can be directly connected to another component or may exist at the same time. When a component is considered to be “disposed on” another component, it can be set directly on another component or may exist at the same time. In the description of this application, unless otherwise expressly specified and limited, the terms “mounted”, “connected”, “connect”, “fixed” and the like are to be understood in a broad sense, for example, it may be a fixed connection, or a detachable connection, or an integral connection; it may also be a mechanical connection or an electrical connection; and it may be a direct connection or indirect connection through an intermediate medium, and may be the interior communication between two elements or the interaction relationship between two elements. For a person of ordinary skill in the art, the specific meaning of the forgoing terms in this application may be understood according to specific circumstances.

Unless otherwise defined, all technical and scientific terms used herein have the same meanings as commonly understood by a person skilled in the technical field to which this application pertains. The terms used herein in the specification of this application are merely for the purpose of describing specific embodiments and are not intended to limit this application. The terms “including” and “provide” and any variations thereof in the description and claims of this application and in the description of the drawings above are intended to cover non-exclusive inclusion.

In the description of the embodiments of this application, the technical terms “first”, “second”, and the like are merely used to distinguish between different objects, and shall not be construed as any indication or implication of relative importance or any implicit indication of the quantity, particular sequence or primary-secondary relationship of the technical features indicated. In the description of the embodiments of this application, “a plurality of” means two or more unless otherwise expressly and specifically defined.

“Embodiments” referred to in the present application mean that a particular feature, structure, or characteristic described in connection with embodiments can be included in at least one embodiment of the present application. The occurrence of the phrase at various locations in the description does not necessarily all refer to the same embodiment, nor is it a separate or alternative embodiment that is mutually exclusive with other embodiments. It is hereby noted that where there is no conflict, the implementations in this application may be mutually combined.

It is hereby noted that the thickness, length, width, and other dimensions of the various components in the embodiments of this application, as well as the overall thickness, length, width, and other dimensions of an integrated apparatus, shown in the drawings, are merely exemplary illustrations and shall not constitute any limitation on this application.

Embodiments of this application disclose an electrochemical apparatus, including a first housing, a second housing, and a battery cell assembly. The first housing includes a first wall, a second wall, a third wall, a fourth wall and a fifth wall, the first wall and the third wall are disposed in a first direction, the second wall and the fourth wall are disposed in a second direction, the second wall is coupled and electrically connected to both the first wall and the third wall, the fourth wall is coupled and electrically connected to both the first wall and the third wall, the fifth wall is coupled and electrically connected to the first wall, the second wall, the third wall and the fourth wall, the first wall, the second wall, the third wall, the fourth wall and the fifth wall form a concave portion, the battery cell assembly is disposed in the concave portion, and the first direction is perpendicular to the second direction. The second housing is separated from the fifth wall and is connected to the first wall, the second wall, the third wall and the fourth wall, the second housing and the fifth wall are disposed in a third direction, and the third direction is perpendicular to the first direction and the second direction. The first housing is provided with a first insulation layer, and the first insulation layer coats a part of a surface of the first wall. The first wall includes a first region, the first region is exposed to the first insulation layer, and the first region is electrically connected to the second housing.

In the above electrochemical apparatus, the first region exposed to the first insulation layer on the first wall is electrically connected to the second housing, so that the first housing and the second housing are electrically connected to form an electrostatic shield, which is beneficial to reducing the effect of an external electric field on the interior of the electrochemical apparatus.

Embodiments of this application are further illustrated below with reference to the accompanying drawings.

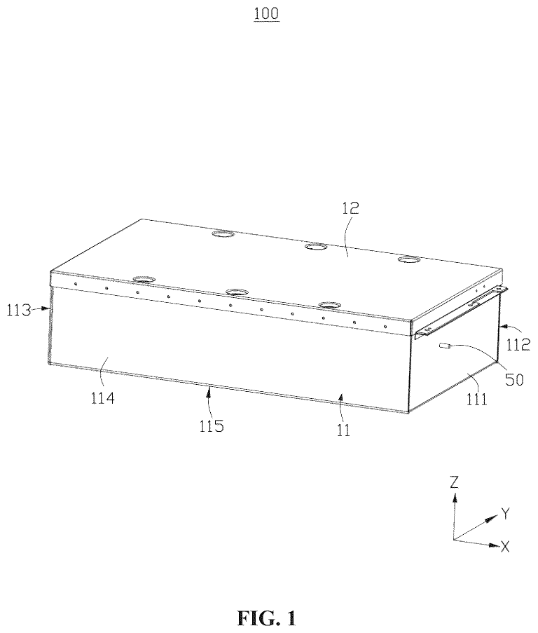

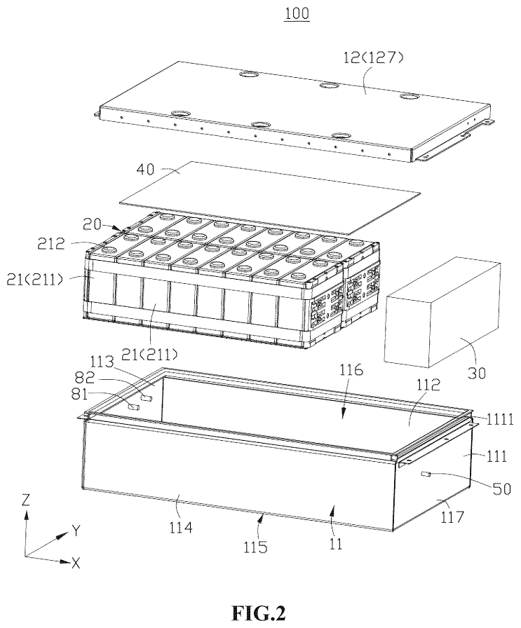

As shown in FIG. 1 and FIG. 2, an implementation of this application provides an electrochemical apparatus 100, including a first housing 11, a second housing 12, and a battery cell assembly 20.

The first housing 11 includes a first wall 111, a second wall 112, a third wall 113, a fourth wall 114 and a fifth wall 115, the first wall 111 and the third wall 113 are disposed in a first direction X, the second wall 112 and the fourth wall 114 are disposed in a second direction Y, the second wall 112 is coupled and electrically connected to both the first wall 111 and the third wall 113, the fourth wall 114 is coupled and electrically connected to both the first wall 111 and the third wall 113, the fifth wall 115 is coupled and electrically connected to the first wall 111, the second wall 112, the third wall 113 and the fourth wall 114, the first wall 111, the second wall 112, the third wall 113, the fourth wall 114 and the fifth wall 115 form a concave portion 116, and the battery cell assembly 20 is disposed in the concave portion 116. The first direction X is perpendicular to the second direction Y.

In one embodiment, the first wall 111, the second wall 112, the third wall 113, the fourth wall 114, and the fifth wall 115 are made of the same material and are all made of metal. In one embodiment, the first housing 11 forms the first wall 111, the second wall 112, the third wall 113, the fourth wall 114, and the fifth wall 115 by a sheet metal process, which is beneficial to simplifying the manufacturing process of the first housing 11 and saving the manufacturing cost of the electrochemical apparatus 100. In one embodiment, materials of the first wall 111, the second wall 112, the third wall 113, the fourth wall 114, and the fifth wall 115 include, but are not limited to, any one of copper, copper alloy, aluminum and aluminum alloy.

The second housing 12 is separated from the fifth wall 115 and is connected to the first wall 111, the second wall 112, the third wall 113 and the fourth wall 114, the second housing 12 and the fifth wall 115 are disposed in a third direction Z, and the third direction Z is perpendicular to the first direction X and the second direction Y.

In one embodiment, the second housing 12 includes a metal substrate 127. In one embodiment, the material of the metal substrate 127 of the second housing 12 includes, but is not limited to, any one of copper, copper alloy, aluminum and aluminum alloy. In one embodiment, the second housing 12 is manufactured by a sheet metal process, which is beneficial to simplifying the manufacturing process of the second housing 12 and saving the manufacturing cost of the electrochemical apparatus 100.

The first housing 11 is provided with a first insulation layer 117, and the first insulation layer 117 coats a part of a surface of the first wall 111. The first wall 111 includes a first region 1111, the first region 1111 is located on a side face of the first wall 111 facing the second housing 12, the first region 1111 is exposed to the first insulation layer 117, and the first region 1111 is connected to the second housing 12 and electrically connected to the metal substrate 127 of the second housing 12. In one embodiment, the first insulation layer 117 further coats at least a part of a surface of the second wall 112, at least a part of a surface of the third wall 113, at least a part of a surface of the fourth wall 114, and at least a part of a surface of the fifth wall 115. The first insulation layer 117 can protect the first wall 111, the second wall 112, the third wall 113, the fourth wall 114, and the fifth wall 115, reduce the conditions of the first wall 111, the second wall 112, the third wall 113, the fourth wall 114, and the fifth wall 115 such as rust and damage, and also reduce the risk of short-circuiting of the electrochemical apparatus 100.

In the above electrochemical apparatus 100, the first region 1111 exposed to the first insulation layer 117 on the first wall 111 is electrically connected to the second housing 12, so that the first housing 11 and the second housing 12 are electrically connected to form an electrostatic shield, which is beneficial to reducing the effect of an external electric field on the interior of the electrochemical apparatus 100.

In this application, the electrostatic shield refers to that a conductor shell formed by electrical connection between the first housing 11 and the second housing 12 plays a role in protecting the interior, so that the interior is not affected by the external electric field.

In one embodiment, the first insulation layer 117 is formed on the surface of the first wall 111 by spraying, which is beneficial to simplifying the process of connecting the first insulation layer 117 to the first wall 111 and saving the manufacturing cost of the electrochemical apparatus 100. In one embodiment, the material of the first insulation layer 117 includes, but is not limited to, one of polytetrafluoroethylene, silicone, zirconium oxide ceramic coating, and chromium oxide ceramic coating.

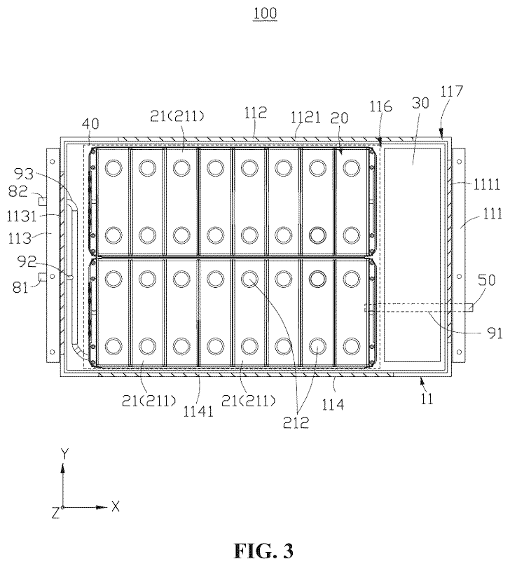

As shown in FIG. 2 and FIG. 3, in one embodiment, the electrochemical apparatus 100 further includes a circuit board 30, the circuit board 30 is disposed in the concave portion 116, and electrically connected to the battery cell assembly 20, and the circuit board 30 may be configured to control charging and discharging of the battery cell assembly 20.

In one embodiment, the circuit board 30 includes a battery management system (BMS) assembly. The BMS assembly includes a plurality of electronic components, and the plurality of electronic components can realize functions of data acquisition, control, protection, communication, power calculation, signal transmission, power transmission, etc. for the battery cell assembly 20.

In one embodiment, when viewed in the third direction Z, the circuit board 30 is located between the first wall 111 and the battery cell assembly 20, which is beneficial to optimizing the internal layout of the electrochemical apparatus 100, improving the space utilization rate of the electrochemical apparatus 100, and improving the energy density of the electrochemical apparatus 100.

In other embodiments, in the third direction Z, the circuit board 30 is located between the second housing 12 and the battery cell assembly 20 (not shown), which is beneficial to reducing the length of the electrochemical apparatus 100 in the first direction X, and by means of the space of the electrochemical apparatus 100 in the third direction Z, the space utilization rate of the electrochemical apparatus 100 is improved, and the energy density of the electrochemical apparatus 100 is improved.

In one embodiment, the battery cell assembly 20 includes a plurality of battery cell units 21, all of which are stacked in the first direction X and/or the second direction Y. In one embodiment, all the battery cell units 21 are connected in series. In one embodiment, all the battery cell units 21 are connected in parallel. In one embodiment, all the battery cell units 21 are connected in series and in parallel.

In one embodiment, each battery cell unit 21 includes a battery cell body 211, an electrode assembly (not shown), and electrode terminals 212, the electrode assembly is disposed in the battery cell body 211, a part of the electrode terminals 212 is disposed in the battery cell body 211 and connected to the electrode assembly, and an other part of the electrode terminals 212 extends out of the battery cell body 211. Different battery cell units 21 are electrically connected through the electrode terminals 212.

In one embodiment, each battery cell unit 21 includes two electrode terminals 212, one of the two electrode terminals 212 is a positive terminal, and the other is a negative terminal.

In one embodiment, each electrode assembly includes a positive electrode plate, a negative electrode plate, and a separator (not shown), the separator is disposed between the positive electrode plate and the negative electrode plate, and the positive electrode plate, the separator and the negative electrode plate are formed into the electrode assembly by stacking or coiling. The positive terminal is electrically connected to the positive electrode plate, and the negative terminal is electrically connected to the negative electrode plate.

In one embodiment, the electrochemical apparatus 100 further includes a first structural member 40, the first structural member 40 is disposed in the concave portion 116, and at least a part of the first structural member 40 is located between the battery cell assembly 20 and the second housing 12 in the third direction Z, and connected to the battery cell assembly 20 and the second housing 12. By disposing the first structural member 40, the first structural member 40 is conducive to providing a filler protection effect, reducing the impact risk of the second housing 12 and the battery cell assembly 20, and improving the seismic performance of the electrochemical apparatus 100.

In one embodiment, the first structural member 40 also serves as an insulating guard to reduce the risk of short-circuiting of the battery cell assembly 20.

In one embodiment, the material of the first structural member 40 includes, but is not limited to, any one of foam, and plastic sheet, and the plastic sheet includes any one of PC/ABS plates, and polytetrafluoroethylene plates.

In one embodiment, the electrochemical apparatus 100 further includes an electrode 50, the electrode 50 is disposed on the first wall 111 and electrically connected to the first housing 11, and a part of the electrode 50 is exposed outside the first housing 11 and the first insulation layer 117. The electrode 50 may be used as a grounding terminal to ground a conductive shell formed by the first housing 11 and the second housing 12, which is beneficial to reducing the effect of an electric field inside the electrochemical apparatus 100 on a device in the external environment. Moreover, the electrode 50 is disposed on the first wall 111, which is beneficial to reducing interference or influence on the electrode 50 when a plurality of electrochemical apparatuses 100 are arranged in the second direction Y or the third direction Z. In other embodiments, the electrode 50 may also be disposed on any of the second wall 112, the third wall 113, the fourth wall 114, and the fifth wall 115.

In one embodiment, the electrode 50 is connected to the first wall 111 by welding, which is beneficial to improving the stability of connecting the electrode 50 to the first wall 111 and improving the seismic performance of the electrochemical apparatus 100. In one embodiment, the first wall 111 is provided with a through hole, and a part of the electrode 50 extends out of the first housing 11 through the through hole.

In one embodiment, the material of the electrode 50 includes, but is not limited to, any one of copper, copper alloy, aluminum, aluminum alloy and nickel alloy.

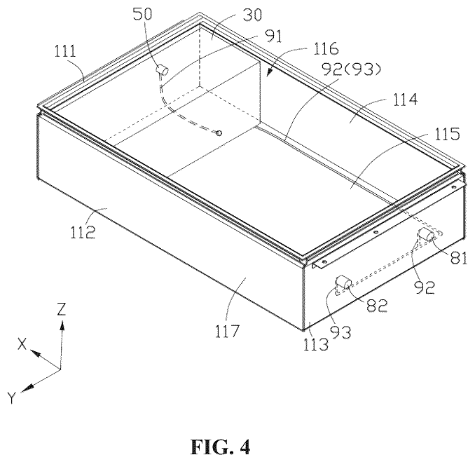

As shown in FIG. 4, in one embodiment, the electrochemical apparatus 100 further includes a first connector 91, and the first connector 91 is disposed in the concave portion 116 and connected to the electrode 50 and the first housing 11. By providing the first connector 91, it is advantageous to electrically connect the first wall 111 and the fifth wall 115 at an equal potential, improving the electrostatic shielding performance of the electrochemical apparatus 100.

In one embodiment, the first connector 91 is connected to the fifth wall 115, so that the electrode 50, the first wall 111, the first connector 91, and the fifth wall 115 are electrically connected, which is beneficial to further maintaining the equal potential of the first wall 111 and the fifth wall 115, and improving the electrostatic shielding performance of the electrochemical apparatus 100.

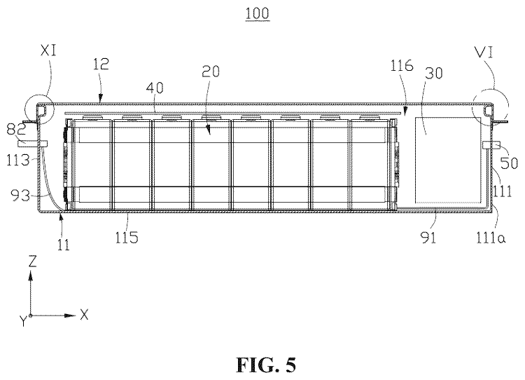

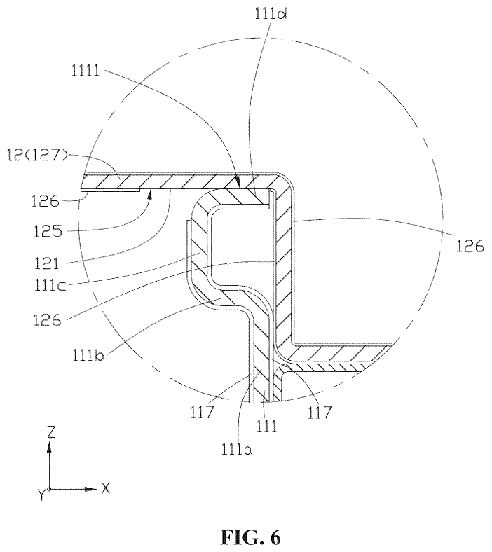

As shown in FIG. 5 and FIG. 6, in one embodiment, the second housing 12 is provided with a second insulation layer 126, and the second insulation layer 126 coats a part of a surface of the second housing 12. The second insulation layer 126 provides protective insulation, which is beneficial to prolonging the service life of the second housing 12, and also is beneficial to reducing the risk of short-circuiting of the electrochemical apparatus 100, and reducing the effect of the external electric field on the interior of the electrochemical apparatus 100.

In one embodiment, the second housing 12 includes a first connection region 121, the first connection region 121 is exposed to the second insulation layer 126, and the first connection region 121 is connected to the first region 1111, such that the second housing 12 is electrically connected to the first housing 11.

In one embodiment, the second housing 12 includes a first face 125, the first face 125 faces the first housing 11, the first connection region 121 is located on the first face 125, and the second insulation layer 126 coats a part of the surface of the first face 125. The first face 125 is a part of the surface of the metal substrate 127, so that the second housing 12 is electrically connected to the first housing 11 when the first connection region 121 is electrically connected to the first region 1111.

In one embodiment, the first wall 111 includes a first segment 111a, a second segment 111b, a third segment 111c, and a fourth segment 111d connected in sequence, the second segment 111b connects the first segment 111a and the third segment 111c, and the third segment 111c connects the second segment 111b and the fourth segment 111d.

At least a part of the fourth segment 111d is exposed to the first insulation layer 117, the first region 1111 is located on the fourth segment 111d, and when viewed in the second direction Y, the second segment 111b, the third segment 111c, and the fourth segment 111d form a C-shaped structure. When the second housing 12 is connected to the first housing 11 through the first connection region 121 and the first region 1111, the C-shaped structural region of the first wall 111 can play an elastic buffer role to improve the stability of the electrical connection between the first connection region 121 and the first region 1111.

Moreover, when viewed in the second direction Y, the fourth segment 111d is disposed extending in the first direction X, which is beneficial to increasing the length of the first region 1111 in the first direction X, and improving the stability of the electrical connection between the first connection region 121 and the first region 1111.

In one embodiment, at least a part of the surface of the first segment 111a, at least a part of the surface of the second segment 111b, and at least a part of the surface of the third segment 111c are provided with the first insulation layer 117, which is beneficial to protecting the first wall 111 and reducing the risk of the first wall 111 being damaged by an external object or rusting.

In one embodiment, the first segment 111a is connected to the second insulation layer 126 on the surface of the second housing 12 through the first insulation layer 117 on the surface, which is beneficial to playing a limiting and insulating role, and reducing the risk of electrical connection between the first housing 11 and the second housing 12 due to friction or collision resulting in damage to the first insulation layer 117 and the second insulation layer 126.

In one embodiment, the end of the first housing 11 in the first direction X is connected to the second housing 12 via connection of the first insulation layer 117 and the second insulation layer 126, which is beneficial to playing a limiting and insulating role, and reducing the risk of electrical connection between the first housing 11 and the second housing 12 due to friction or collision resulting in damage to the first insulation layer 117 and the second insulation layer 126.

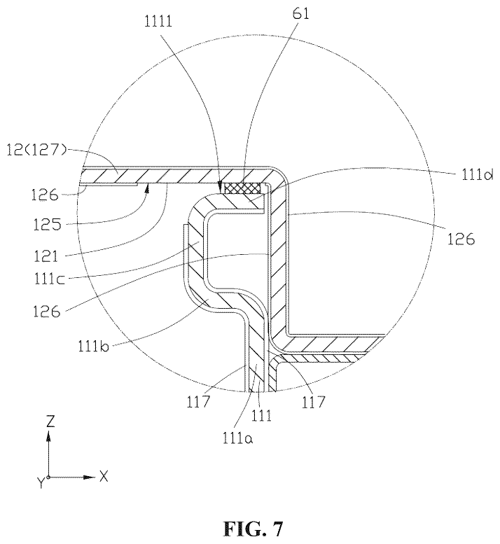

As shown in FIG. 7, in one embodiment, the electrochemical apparatus 100 further includes a first conductive member 61, and the first conductive member 61 is connected to the first region 1111 and the first connection region 121, which is beneficial to improving the stability of electrical connection between the first housing 11 and the second housing 12 and improving the seismic performance of the electrochemical apparatus 100.

In one embodiment, the first conductive member 61 includes a conductive adhesive tape, and the conductive adhesive tape is adhesively connected to the first region 1111 and the first connection region 121, which is beneficial to improving the stability of connecting the first conductive member 61 to the first region 1111 and the first connection region 121, and improving the seismic performance of the electrochemical apparatus 100.

In one embodiment, the conductive adhesive tape includes a substrate layer and a conductive layer (not shown) disposed on the surface of the substrate layer, and the conductive layer makes contact with and is electrically connected to the first region 1111 and the first connection region 121.

In one embodiment, the first conductive member 61 is formed from a conductive adhesive, the conductive adhesive includes a resin matrix and a conductive filler, the resin matrix includes one or more of an epoxy resin, an organosilicone resin, a polyimide resin, a phenolic resin, a urethane, and an acrylic resin, and the conductive filler includes one or more of powder of gold, silver, copper, aluminum, zinc, iron and nickel, graphite and some conductive compounds.

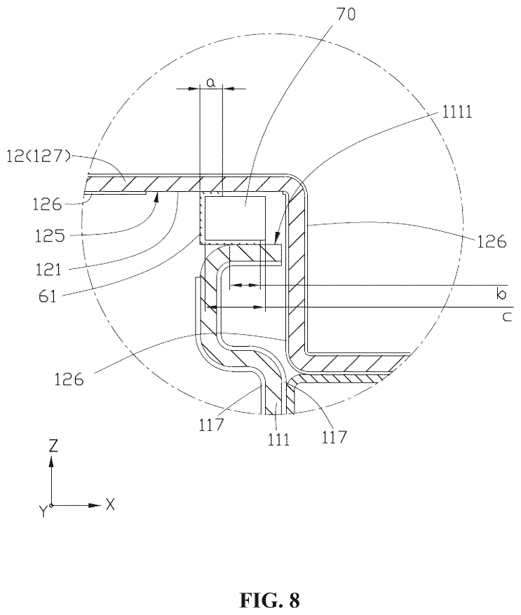

As shown in FIG. 8, in some embodiments, the electrochemical apparatus 100 further includes a first insulator 70, and a part of the first insulator 70 is located between the first face 125 and the first wall 111, and connected to the first face 125 and the first wall 111. The first insulator 70 may play a sealing and protecting role, and reduce the risk of outside debris entering the interior of the electrochemical apparatus 100 through a gap between the first face 125 and the first wall 111.

Optionally, the first insulator 70 is connected to the first region 1111 and the first connection region 121.

In one embodiment, the first insulator 70 includes a seal ring. In one embodiment, the material of the seal ring includes, but is not limited to, any of natural rubber, silicone rubber, ethylene propylene rubber, fluorinated rubber, and nitrile rubber.

In one embodiment, the first conductive member 61 is connected to the first insulator 70 and coats a part of a surface of the first insulator 70. The support function of the first insulator 70 is beneficial to improving the stability of connection of the first conductive member 61 to the first region 1111 and the first connection region 121 and further improving the seismic performance of the electrochemical apparatus 100.

In one embodiment, the first conductive member 61 is a surface conductive coating applied to the first insulator 70. Optionally, the first conductive member 61 is formed on the surface of the first insulator 70 by means of electroplating. Optionally, the first conductive member 61 is conductive paint.

In one embodiment, when viewed in the third direction Z, there is an overlap of the projection of the first conductive member 61, the projection of the first insulator 70, and the projection of the first region 1111, and there is an overlap of the projection of the first conductive member 61, the projection of the first insulator 70, and the projection of the first connection region 121, which is beneficial to improving the stability of connecting the first conductive member 61 to the first region 1111 and the first connection region 121, and improving the seismic performance of the electrochemical apparatus 100.

In one embodiment, in the first direction X, a length of a connection region of the first connection region 121 with the first conductive member 61 is a, a length of the first insulator 70 is c, and a≤c/2, which is beneficial to ensuring a contact area between the first insulator 70 and the second housing 12, and reducing the risk of outside debris entering the interior of the electrochemical apparatus 100 through the gap between the first face 125 and the first wall 111.

In one embodiment, in the first direction X, a length of a connection region of the first region 1111 with the first conductive member 61 is b, and c/2≤ b<c, which is beneficial to ensuring a contact area between the first conductive member 61 and the first region 1111, reducing the risk of failure of the electrical connection between the first conductive member 61 and the first region 1111, and reducing the effect of the external electric field on the interior of the electrochemical apparatus 100.

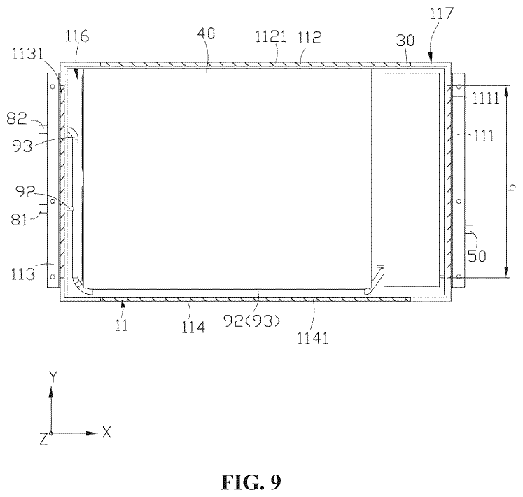

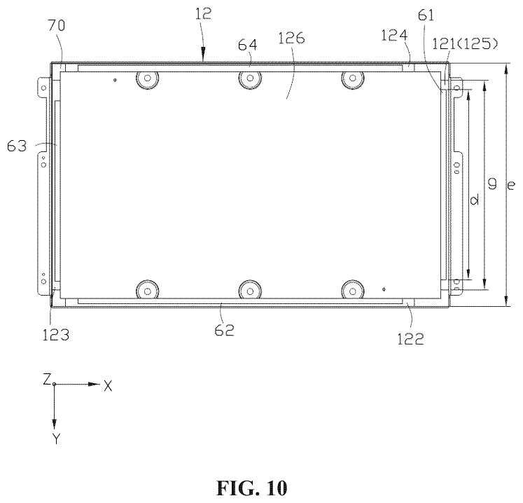

As shown in FIG. 9 and FIG. 10, in one embodiment, in the second direction Y, a length of the first conductive member 61 is d, a length of the first insulator 70 is e, and e/2<d<e, which is beneficial to ensuring a contact area between the first conductive member 61 and the first region 1111 as well as between the first conductive member 61 and the first connection region 121, reducing the risk of failure of the electrical connection between the first conductive member 61 and the first region 1111 as well as between the first conductive member 61 and the first connection region 121, and reducing the effect of the external electric field on the interior of the electrochemical apparatus 100.

In one embodiment, in the second direction Y, a length of the first region 1111 is f, and f>d, which is beneficial to ensuring a contact area between the first conductive member 61 and the first region 1111, reducing the risk of failure of the electrical connection between the first conductive member 61 and the first region 1111, and reducing the effect of the external electric field on the interior of the electrochemical apparatus 100.

In one embodiment, in the second direction Y, a length of the first connection region 121 is g, and g>d, which is beneficial to ensuring a contact area between the first conductive member 61 and the first connection region 121, reducing the risk of failure of the electrical connection between the first conductive member 61 and the first connection region 121, and reducing the effect of the external electric field on the interior of the electrochemical apparatus 100.

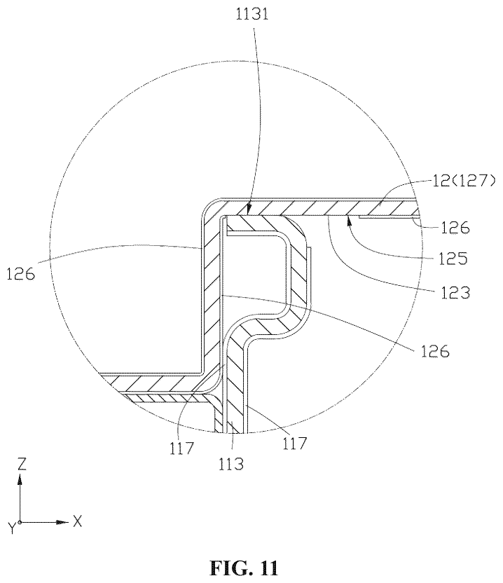

Referring to FIG. 11, additional structures in the electrochemical apparatus 100 are further described based on any of the preceding embodiments.

In one embodiment, the first insulation layer 117 also coats a part of the surface of the third wall 113, which is beneficial to achieving insulating protection for the third wall 113, prolonging the service life of the first housing 11, and also reducing the risk of short-circuiting of the electrochemical apparatus 100, and reducing the effect of the external electric field on the interior of the electrochemical apparatus 100.

In one embodiment, the third wall 113 further includes a third region 1131, the third region 1131 is exposed to the first insulation layer 117, and the third region 1131 is connected to the metal substrate 127 of the second housing 12, which is beneficial to further improving the stability of the electrical connection between the first housing 11 and the second housing 12, reducing the risk of failure of the electrical connection between the first housing 11 and the second housing 12, and reducing the effect of the external electric field on the interior of the electrochemical apparatus 100.

In one embodiment, the first face 125 further includes a third connection region 123, the third connection region 123 is exposed to the second insulation layer 126, and the third connection region 123 is connected to the third region 1131, which is beneficial to further improving the stability of the electrical connection between the first housing 11 and the second housing 12, reducing the risk of failure of the electrical connection between the first housing 11 and the second housing 12, and reducing the effect of the external electric field on the interior of the electrochemical apparatus 100.

In one embodiment, the end of the first housing 11 in the direction opposite to the first direction X is connected to the second housing 12 via connection of the first insulation layer 117 and the second insulation layer 126, which is beneficial to playing a limiting and insulating role, and reducing the risk of electrical connection between the first housing 11 and the second housing 12 due to friction or collision resulting in damage to the first insulation layer 117 and the second insulation layer 126.

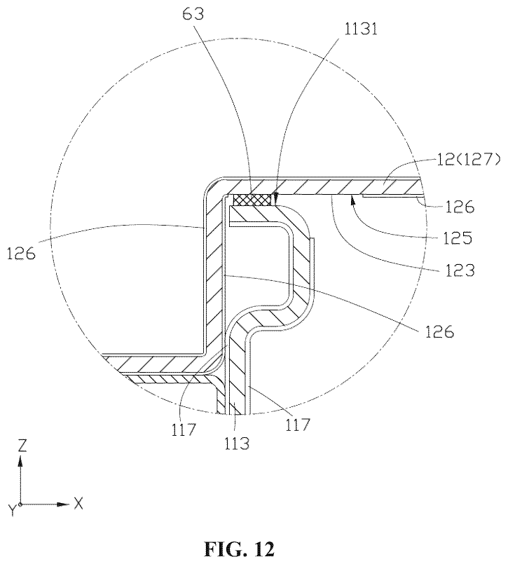

As shown in FIG. 12, in one embodiment, the electrochemical apparatus 100 further includes a third conductive member 63, and the third conductive member 63 is connected to the third region 1131 and the third connection region 123, which is beneficial to improving the stability of electrical connection between the first housing 11 and the second housing 12 and improving the seismic performance of the electrochemical apparatus 100.

In one embodiment, the third conductive member 63 includes a conductive adhesive tape, and the conductive adhesive tape is adhesively connected to the third region 1131 and the third connection region 123, which is beneficial to improving the stability of connecting the third conductive member 63 to the third region 1131 and the third connection region 123, and improving the seismic performance of the electrochemical apparatus 100. In one embodiment, the conductive adhesive tape includes a substrate layer and a conductive layer (not shown) disposed on the surface of the substrate layer, and the conductive layer makes contact with and is electrically connected to the third region 1131 and the third connection region 123.

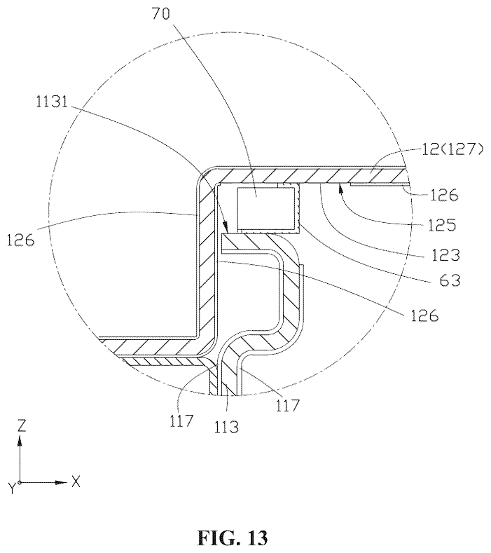

As shown in FIG. 13, in one embodiment, a part of the first insulator 70 is further located between the first face 125 and the third wall 113, and connected to the first face 125 and the third wall 113, which is beneficial to reducing the risk of outside debris entering the interior of the electrochemical apparatus 100 through a gap between the first face 125 and the third wall 113. Optionally, the first insulator 70 is connected to the third region 1131 and the third connection region 123.

In one embodiment, the third conductive member 63 is connected to the first insulator 70 and coats a part of the surface of the first insulator 70. When viewed in the third direction Z, there is an overlap of the projection of the third conductive member 63, the projection of the first insulator 70, and the projection of the first region 1111, and there is an overlap of the projection of the third conductive member 63, the projection of the first insulator 70, and the projection of the first connection region 121. The support function of the first insulator 70 is beneficial to improving the stability of connecting the third conductive member 63 to the first region 1111 and the first connection region 121, and further improving the seismic performance of the electrochemical apparatus 100.

In one embodiment, the third conductive member 63 is a surface conductive coating applied to the first insulator 70. Optionally, the third conductive member 63 is formed on the surface of the first insulator 70 by means of electroplating. Optionally, the third conductive member 63 is conductive paint.

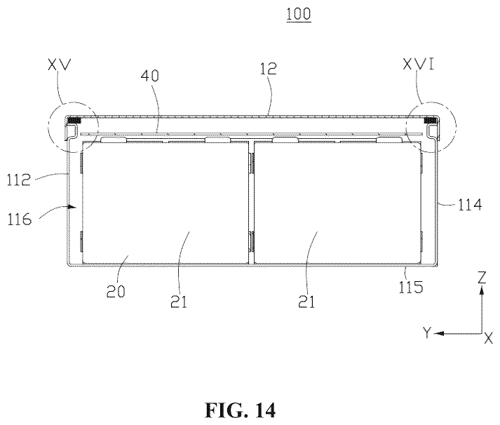

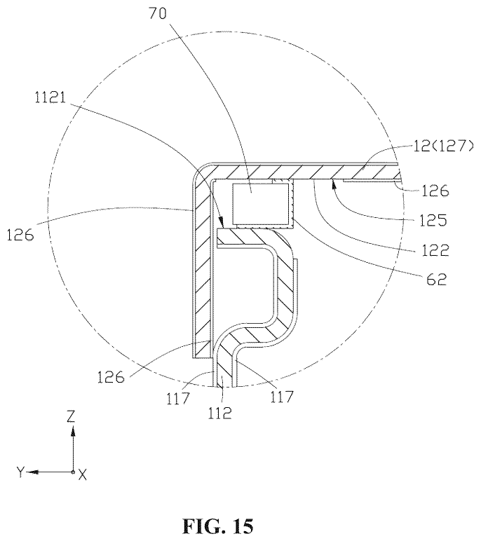

As shown in FIG. 14 and FIG. 15, in one embodiment, the first insulation layer 117 also coats a part of the surface of the second wall 112, which is beneficial to achieving insulating protection for the second wall 112, prolonging the service life of the first housing 11, and also reducing the risk of short-circuiting of the electrochemical apparatus 100, and reducing the effect of the external electric field on the interior of the electrochemical apparatus 100.

In one embodiment, the second wall 112 further includes a second region 1121, the second region 1121 is exposed to the first insulation layer 117, and the second region 1121 is connected to the metal substrate 127 of the second housing 12, which is beneficial to further improving the stability of the electrical connection between the first housing 11 and the second housing 12, reducing the risk of failure of the electrical connection between the first housing 11 and the second housing 12, and reducing the effect of the external electric field on the interior of the electrochemical apparatus 100.

In one embodiment, the first face 125 further includes a second connection region 122, the second connection region 122 is exposed to the second insulation layer 126, and the second connection region 122 is connected to the second region 1121, which is beneficial to further improving the stability of the electrical connection between the first housing 11 and the second housing 12, reducing the risk of failure of the electrical connection between the first housing 11 and the second housing 12, and reducing the effect of the external electric field on the interior of the electrochemical apparatus 100.

In one embodiment, the end of the first housing 11 in the second direction Y is connected to the second housing 12 via connection of the first insulation layer 117 and the second insulation layer 126, which is beneficial to playing a limiting and insulating role, and reducing the risk of electrical connection between the first housing 11 and the second housing 12 due to friction or collision resulting in damage to the first insulation layer 117 and the second insulation layer 126.

In one embodiment, a part of the first insulator 70 is located between the first face 125 and the second wall 112, and connected to the first face 125 and the second wall 112, which is beneficial to reducing the risk of outside debris entering the interior of the electrochemical apparatus 100 through a gap between the first face 125 and the second wall 112.

In one embodiment, the electrochemical apparatus 100 further includes a second conductive member 62, and the second conductive member 62 is connected to the second region 1121 and the second connection region 122, which is beneficial to improving the stability of the electrical connection between the first housing 11 and the second housing 12 and improving the seismic performance of the electrochemical apparatus 100.

In one embodiment, the second conductive member 62 includes a conductive adhesive tape, and the conductive adhesive tape is adhesively connected to the second region 1121 and the second connection region 122, which is beneficial to improving the stability of connecting the second conductive member 62 to the second region 1121 and the second connection region 122, and improving the seismic performance of the electrochemical apparatus 100. In one embodiment, the conductive adhesive tape includes a substrate layer and a conductive layer (not shown) disposed on the surface of the substrate layer, and the conductive layer makes contact with and is electrically connected to the second region 1121 and the second connection region 122.

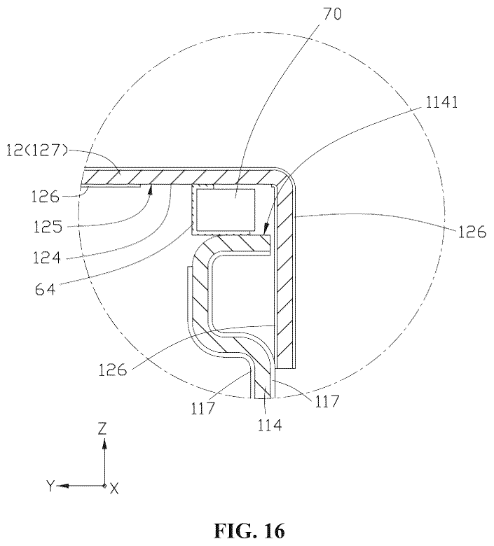

As shown in FIG. 16, in one embodiment, the first insulation layer 117 also coats a part of the surface of the fourth wall 114, which is beneficial to achieving insulating protection for the fourth wall 114, prolonging the service life of the first housing 11, and also reducing the risk of short-circuiting of the electrochemical apparatus 100, and reducing the effect of the external electric field on the interior of the electrochemical apparatus 100.

In one embodiment, the fourth wall 114 further includes a fourth region 1141, the fourth region 1141 is exposed to the first insulation layer 117, and the fourth region 1141 is connected to the metal substrate 127 of the second housing 12, which is beneficial to further improving the stability of the electrical connection between the first housing 11 and the second housing 12, reducing the risk of failure of the electrical connection between the first housing 11 and the second housing 12, and reducing the effect of the external electric field on the interior of the electrochemical apparatus 100.

In one embodiment, the first face 125 further includes a fourth connection region 124, the fourth connection region 124 is exposed to the second insulation layer 126, and the fourth connection region 124 is connected to the fourth region 1141, which is beneficial to further improving the stability of the electrical connection between the first housing 11 and the second housing 12, reducing the risk of failure of the electrical connection between the first housing 11 and the second housing 12, and reducing the effect of the external electric field on the interior of the electrochemical apparatus 100.

In one embodiment, under the condition that the first housing 11 and the second housing 12 are electrically connected via the first region 1111, the second region 1121, the third region 1131 and the fourth region 1141 may not be disposed.

In one embodiment, under the condition that the first housing 11 and the second housing 12 are electrically connected via the first region 1111, the stability of the electrical connection between the first housing 11 and the second housing 12 is improved by disposing at least one of the second region 1121, the third region 1131 and the fourth region 1141.

In one embodiment, the end of the first housing 11 in the direction opposite to the second direction Y is connected to the second housing 12 via connection of the first insulation layer 117 and the second insulation layer 126, which is beneficial to playing a limiting and insulating role, improving the stability of connection between the first housing 11 and the second housing 12, reducing the risk of relative movement of the first housing 11 and the second housing 12, and further is beneficial to reducing the risk of the electrical connection between the first housing 11 and the second housing 12 due to friction or collision resulting in damage to the first insulation layer 117 and the second insulation layer 126.

In one embodiment, a part of the first insulator 70 is located between the first face 125 and the fourth wall 114, and connected to the first face 125 and the fourth wall 114, which is beneficial to reducing the risk of outside debris entering the interior of the electrochemical apparatus 100 through a gap between the first face 125 and the fourth wall 114. Optionally, the first insulator 70 is connected to the third region 1131 and the third connection region 123.

In one embodiment, the electrochemical apparatus 100 further includes a fourth conductive member 64, and the fourth conductive member 64 is connected to the fourth region 1141 and the fourth connection region 124, which is beneficial to improving the stability of the electrical connection between the first housing 11 and the second housing 12 and improving the seismic performance of the electrochemical apparatus 100.

In one embodiment, the fourth conductive member 64 includes a conductive adhesive tape, and the conductive adhesive tape is adhesively connected to the fourth region 1141 and the fourth connection region 124, which is beneficial to improving the stability of connecting the fourth conductive member 64 to the fourth region 1141 and the fourth connection region 124, and improving the seismic performance of the electrochemical apparatus 100. In one embodiment, the conductive adhesive tape includes a substrate layer and a conductive layer (not shown) disposed on the surface of the substrate layer, and the conductive layer makes contact with and is electrically connected to the fourth region 1141 and the fourth connection region 124.

As shown in FIG. 10, in one embodiment, any two of the first conductive member 61, the second conductive member 62, the third conductive member 63 and the fourth conductive member 64 are separated from each other when viewed in the third direction Z, which is beneficial to reducing the effect of contact interference between different conductive members on assembly of the first housing 11 and the second housing 12, and improving the sealing performance between the first housing 11 and the second housing 12.

As shown in FIG. 2 and FIG. 9, in one embodiment, the electrochemical apparatus 100 further includes a first output terminal 81 and a second output terminal 82, both of the first output terminal 81 and the second output terminal 82 are electrically connected to the circuit board 30, and a part of the first output terminal 81 and a part of the second output terminal 82 are exposed to the first housing 11 and exposed to the first insulation layer 117. The first output terminal 81 and the second output terminal 82 may serve as external terminals of the electrochemical apparatus 100, enabling the electrochemical apparatus 100 to be electrically connected to an external device for charging and discharging.

In one embodiment, the first output terminal 81 and the second output terminal 82 are both disposed on the third wall 113, and when viewed in the third direction Z, the first output terminal 81 and the second output terminal 82 are both disposed on the side of the battery cell assembly 20 back away from the circuit board 30, which is beneficial to reducing the risk of short-circuiting inside the electrochemical apparatus 100.

In one embodiment, one of the first output terminal 81 and the second output terminal 82 is a positive output terminal of the electrochemical apparatus 100 and the other is a negative output terminal of the electrochemical apparatus 100.

In one embodiment, the electrochemical apparatus 100 further includes a second connector 92 and a third connector 93, the second connector 92 and the third connector 93 are both disposed in the concave portion 116, the second connector 92 is connected to the circuit board 30 and the first output terminal 81, and the third connector 93 is connected to the circuit board 30 and the second output terminal 82. By providing the second connector 92 and the third connector 93, the first output terminal 81 and the second output terminal 82 are connected to the circuit board 30, which is beneficial to improving the stability of connecting the first output terminal 81 and the second output terminal 82 to the circuit board 30, and improving the seismic performance of the electrochemical apparatus 100.

In one embodiment, the second connector 92 is plugged into the circuit board 30 via a connection terminal in a pluggable manner, which is beneficial to improving the stability of electrically connecting the second connector 92 to the circuit board 30, and further simplifying the assembly process and improving the assembly efficiency. In one embodiment, the second connector 92 is a wire.

In one embodiment, the third connector 93 is plugged into the circuit board 30 via a connection terminal in a pluggable manner, which is beneficial to improving the stability of electrically connecting the third connector 93 to the circuit board 30, and further simplifying the assembly process and improving the assembly efficiency. In one embodiment, the third connector 93 is a wire.

In one embodiment, a part of the second connector 92 is located between the battery cell assembly 20 and the fourth wall 114, and an other part of the second connector 92 is located between the battery cell assembly 20 and the third wall 113, which is beneficial to optimizing the internal layout of the electrochemical apparatus 100, improving the space utilization rate of the electrochemical apparatus 100, and improving the energy density of the electrochemical apparatus 100.

In one embodiment, a part of the third connector 93 is located between the battery cell assembly 20 and the fourth wall 114, and an other part of the third connector 93 is located between the battery cell assembly 20 and the third wall 113, which is beneficial to optimizing the internal layout of the electrochemical apparatus 100, improving the space utilization rate of the electrochemical apparatus 100, and improving the energy density of the electrochemical apparatus 100.

In summary, in the electrochemical apparatus 100 of this application, the first region 1111 exposed to the first insulation layer 117 on the first wall 111 is electrically connected to the second housing 12, so that the first housing 11 and the second housing 12 are electrically connected to form an electrostatic shield, which is beneficial to reducing the effect of an external electric field on the interior of the electrochemical apparatus 100.

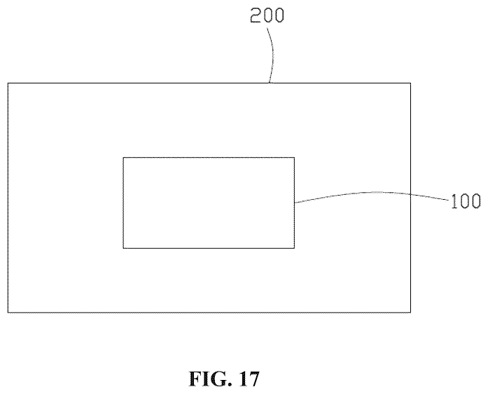

As shown in FIG. 17, the embodiment of this application also provides an electrical device 200, including the electrochemical apparatus 100 described in any of the above embodiments.

In the above electrical device 200, the first region 1111 exposed to the first insulation layer 117 on the first wall 111 is electrically connected to the second housing 12 in the electrochemical apparatus 100, so that the first housing 11 and the second housing 12 are electrically connected to form an electrostatic shield, which is beneficial to reducing the effect of an external electric field on the interior of the electrochemical apparatus 100, and reducing the effect of performance damage of the electrochemical apparatus 100 caused by the external electric field on the electrical device 200.

In one embodiment, the electrical device 200 includes, but is not limited to, any one of an unmanned aerial vehicle, a two-wheeled electric vehicle, an electric tool, and a robot.

In addition, other changes may be made by persons skilled in the art within the spirit of this application, and certainly, these changes made in accordance with the spirit of this application shall be included in the scope disclosed in this application.

What is claimed is:

1. An electrochemical apparatus, comprising:
a first housing, comprising a first wall, a second wall, a third wall, a fourth wall and a fifth wall; the first wall and the third wall being disposed in a first direction, the second wall and the fourth wall being disposed in a second direction, the second wall being coupled and electrically connected to both the first wall and the third wall, the fourth wall being coupled and electrically connected to both the first wall and the third wall, the fifth wall being coupled and electrically connected to the first wall, the second wall, the third wall and the fourth wall; the first wall, the second wall, the third wall, the fourth wall and the fifth wall forming a concave portion, and the first direction being perpendicular to the second direction;
a second housing, apart from the fifth wall and connected to the first wall, the second wall, the third wall and the fourth wall; the second housing and the fifth wall being disposed along a third direction, and the third direction being perpendicular to the first direction and the second direction; and
a battery cell assembly, disposed in the concave portion; wherein
the first housing is provided with a first insulation layer, and the first insulation layer coats a part of a surface of the first wall; and
the first wall comprises a first region, the first region is exposed to the first insulation layer, and the first region is electrically connected to the second housing.

2. The electrochemical apparatus according to claim 1, further comprising an electrode, the electrode is disposed on the first wall and electrically connected to the first housing, and a part of the electrode is exposed outside the first housing.

3. The electrochemical apparatus according to claim 1, wherein
the second housing is provided with a second insulation layer, and the second insulation layer coats a part of a surface of the second housing; and
the second housing comprises a first connection region, the first connection region is exposed to the second insulation layer, and the first connection region is connected to the first region, the second housing is electrically connected to the first housing.

4. The electrochemical apparatus according to claim 3, wherein
the second housing comprises a first face, the first face faces the first housing, the first connection region is located on the first face, and the second insulation layer coats a part of a surface of the first face; and
the electrochemical apparatus further comprises a first conductive member, and the first conductive member is connected to the first region and the first connection region.

5. The electrochemical apparatus according to claim 4,
further comprising a first insulator, and a part of the first insulator is located between the first face and the first wall, and the first insulator is connected to the first face and the first wall.

6. The electrochemical apparatus according to claim 5, wherein
the first conductive member is connected to the first insulator and coats a part of a surface of the first insulator; and
in the first direction, a length of a connection region of the first connection region with the first conductive member is a, a length of a connection region of the first region with the first conductive member is b, a length of the first insulator is c, a≤ c/2, and c/2≤b<c.

7. The electrochemical apparatus according to claim 5, wherein
the first conductive member is connected to the first insulator and coats a part of a surface of the first insulator; and
in the second direction, a length of the first conductive member is d, a length of the first insulator is e, and e/2<d<e.

8. The electrochemical apparatus according to claim 4, wherein in the second direction, a length of the first region is greater than a length of the first conductive member, and a length of the first connection region is greater than the length of the first conductive member.

9. The electrochemical apparatus according to claim 5, wherein the first insulation layer further coats a part of a surface of the third wall, the third wall comprises a third region, the third region is exposed to the first insulation layer, and the third region is connected to the second housing; and
a part of the first insulator is located between the first face and the third wall, and the first insulator is connected to the first face and the third wall.

10. The electrochemical apparatus according to claim 9, wherein
the second housing comprises a third connection region, the third connection region is exposed to the second insulation layer, and the third connection region is connected to the third region.

11. The electrochemical apparatus according to claim 10,
further comprising a third conductive member, and the third conductive member is connected to the third region and the third connection region.

12. The electrochemical apparatus according to claim 9, wherein
the first insulation layer further coats a part of a surface of the second wall and a part of a surface of the fourth wall, the second wall comprises a second region, the second region is exposed to the first insulation layer, the fourth wall comprises a fourth region, the fourth region is exposed to the first insulation layer, and both the second region and the fourth region are connected to the second housing;
a part of the first insulator is located between the first face and the second wall, and connected to the first face and the second wall; and
an other part of the first insulator is located between the first face and the fourth wall, and connected to the first face and the fourth wall.

13. The electrochemical apparatus according to claim 12, wherein the second housing comprises:
a second connection region, the second connection region being exposed to the second insulation layer, and the second connection region being connected to the second region;
a third connection region, the third connection region being exposed to the second insulation layer, and the third connection region being connected to the third region; and
a fourth connection region, the fourth connection region being exposed to the second insulation layer, and the fourth connection region being connected to the fourth region.

14. The electrochemical apparatus according to claim 13, further comprising
a second conductive member, connected to the second region and the second connection region;
a third conductive member, connected to the third region and the third connection region; and
a fourth conductive member, connected to the fourth region and the fourth connection region.

15. The electrochemical apparatus according to claim 14, wherein any two of the first conductive member, the second conductive member, the third conductive member and the fourth conductive member are separated from each other when viewed in the third direction.

16. The electrochemical apparatus according to claim 2, further comprising a first connector, and the first connector is connected to the electrode and the first housing.

17. The electrochemical apparatus according to claim 16,
further comprising a circuit board, the circuit board is disposed in the concave portion, and the circuit board is connected to the battery cell assembly; and
when viewed in the third direction, the circuit board is located between the first wall and the battery cell assembly.

18. The electrochemical apparatus according to claim 1, further comprising
a circuit board, disposed in the concave portion, and connected to the battery cell assembly;
a second connector, disposed in the concave portion, and connected to the circuit board; and
a third connector, disposed in the concave portion, and connected to the circuit board;
a part of the second connector is located between the battery cell assembly and the fourth wall, and an other part of the second connector is located between the battery cell assembly and the third wall; and
a part of the third connector is located between the battery cell assembly and the fourth wall, and an other part of the third connector is located between the battery cell assembly and the third wall.

19. The electrochemical apparatus according to claim 18, further comprising
a first output terminal, disposed on the third wall, a part of the first output terminal being exposed in the first housing, and the second connector being connected to the first output terminal; and
a second output terminal, disposed on the third wall, a part of the second output terminal being exposed in the first housing, and the third connector being connected to the second output terminal.

20. An electrical device, wherein the electrical device comprises the electrochemical apparatus according to claim 1.
